(19) United States
(12) Patent Application Publication
(10) Pub. No.: US 2008/0054971 A1
(43) Pub. Date: Mar. 6, 2008

(54) PULSE WIDTH MODULATION CONTROL CIRCUIT

(76) Inventors: Wenkai Wu, East Greenwich, RI (US); George Schuellein, Narragansett, RI (US)

Correspondence Address: OSTROLENK FABER GERB & SOFFEN, 1180 AVENUE OF THE AMERICAS, NEW YORK, NY, 100368403, US

(21) Appl. No.: 11/774,242

(22) Filed: Jul. 6, 2007

Related U.S. Application Data
(60) Provisional application No. 60/818,873, filed on Jul. 6, 2006.

(51) Int. Cl. H03K 7/00; H03K 7/08

(52) U.S. Cl. 327/172

(57) ABSTRACT

A pulse width modulation control circuit for providing a pulse width modulation signal in accordance with an embodiment of the present application includes a comparator operable to compare a first input to a second input and to provide the pulse width modulation signal based on the comparison, wherein the first input is an error signal and the second input is a ramp signal, wherein a first portion of the ramp is a decreasing ramp signal having a first slew rate and a second portion of the ramp signal is an increasing ramp signal having a second slew rate.

### CROSS-REFERENCE TO RELATED APPLICATIONS

The present application claims benefit of and priority to U.S. Provisional Patent Application Ser. No. 60/818,873 entitled NOVEL PWM TECHNIQUE-PULSE FREQUENCY AND WIDTH MODULATOR filed Jul. 6, 2006, the entire contents of which are hereby incorporated by reference herein.

### BACKGROUND OF THE INVENTION

The present application relates to an improved pulse width modulation control circuit and method. In particular, the present application relates to a control circuit that uses a combination of leading edge, trailing edge and dual edge control architecture.

Conventional pulse width modulation (PWM) control circuits typically utilize either a trailing edge or leading edge control architecture. While each of these architectures have certain advantages, they also have drawbacks. For example, controllers that utilize trailing edge control turn ON at the beginning of every clock. As a result, such control circuits respond to any transient event that occurs while the control circuit is ON, however, are delayed until the next clock cycle if a transient occurs while it is OFF.

In leading edge control, the control circuit turns OFF at the clock cycle and can respond to transients that occur while the control circuit is OFF, but in this case, must wait until the next clock cycle to respond if the transient occurs while it is ON. Thus, in both leading edge and trailing edge control circuits, adjustments depend on the clock pulse, and thus, are subject to clock delays.

In light of these drawbacks, so-called dual-edge control architectures have been developed. In such a dual edge control circuit, the control circuit is not constrained by clock cycles when determining when to turn ON and OFF. The ON/OFF state of the control circuit depends on the error signal. However, as a result, this control architecture is very sensitive to any noise that is introduced to the error signal. For example, it is not unusual for the error signal to be provided from an output of an error amplifier, which may introduce noise to the error signal. As a result, the PWM signal may be corrupted by undesirable pulses.

Accordingly, it would be useful to provide a control circuit for use with pulse width modulation and pulse frequency modulation that avoids the problems noted above.

### SUMMARY OF THE INVENTION

It is an object of the present invention to provide an improved pulse width modulation control circuit and method.

A pulse width modulation control circuit for providing a pulse width modulation signal in accordance with an embodiment of the present application includes a comparator operable to compare a first input to a second input and to provide the pulse width modulation signal based on the comparison, wherein the first input is an error signal and the second input is a ramp signal, wherein a first portion of the ramp is a decreasing ramp signal having a first slew rate and a second portion of the ramp signal is an increasing ramp signal having a second slew rate.

A method of providing a pulse width modulation signal to provide pulse width modulation in accordance with an embodiment of the present application includes comparing an error signal to a ramp signal and generating the pulse width modulation signal based on the comparing step, wherein, the ramp signal includes a first decreasing portion having a first slew rate and a second increasing portion having a second slew rate, wherein a leading edge of a pulse of the pulse width modulation signal is triggered when the first decreasing portion of the ramp signal decreases to match the error signal and a trailing edge of the pulse of the pulse width modulation signal is triggered when the increasing portion of the ramp signal increases to match the error signal.

Other features and advantages of the present invention will become apparent from the following description of the invention which refers to the accompanying drawings.

### BRIEF DESCRIPTION OF THE DRAWING(S)

FIGS. 1A-B illustrate waveforms of a conventional pulse width modulation control circuit utilizing a trailing edge control architecture;

FIGS. 2A-B illustrate waveforms of a conventional pulse width modulation control circuit utilizing a leading edge control architecture;

FIGS. 3A-B illustrate waveforms of a conventional pulse width modulation control circuit utilizing a dual edge control architecture;

FIG. 4 is an illustration of an exemplary pulse width modulation control circuit in accordance with an embodiment of the present invention;

FIGS. 5A-5B illustrate waveforms of the pulse width modulation control circuit of FIG. 4.

FIGS. 6A and 6B are graphs representing data gathered in simulating the pulse width modulation control circuit of FIG. 4.

### DETAILED DESCRIPTION OF PREFERRED EMBODIMENTS OF THE INVENTION

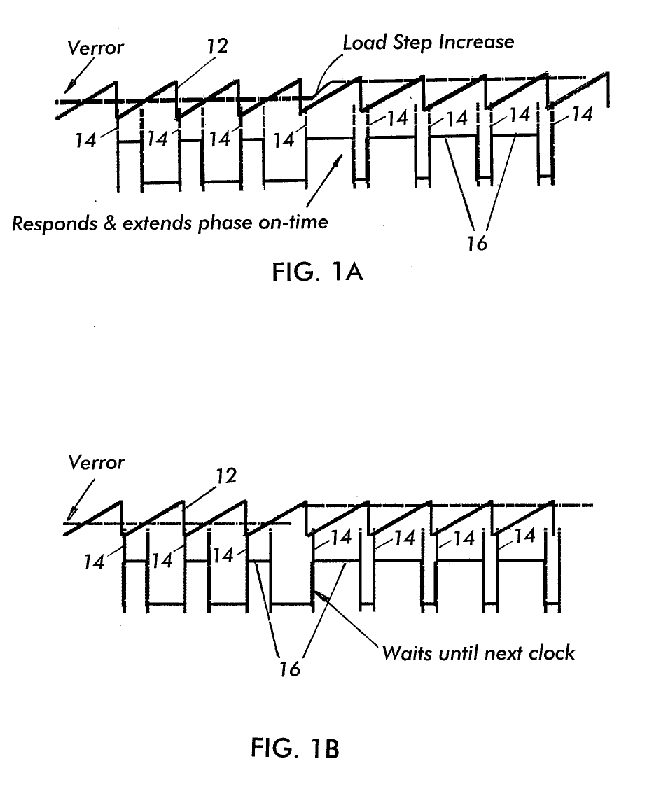

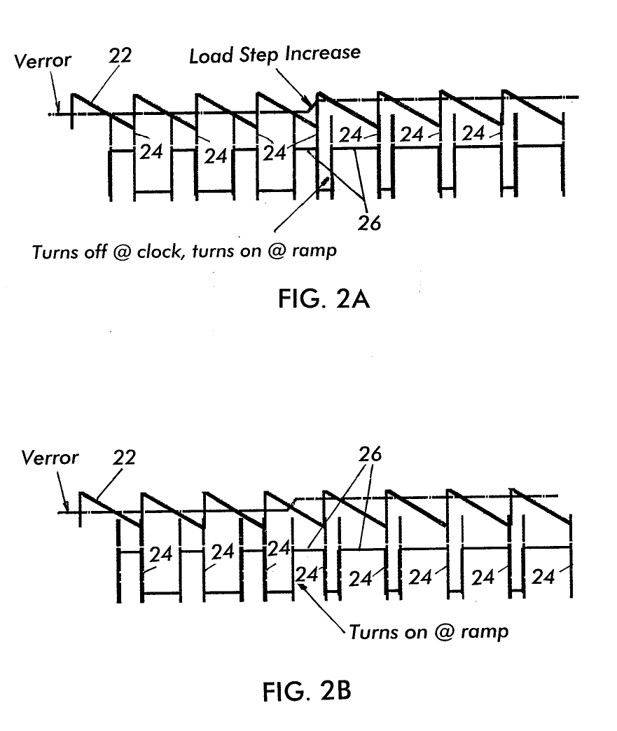

FIGS. 1A-1B illustrate waveforms in a typical trailing edge PWM control architecture. As illustrated, the error signal Verror is shown with an increasing ramp signal 12 superimposed thereon. Typically, these two signals are used to generate the PWM signal 16 via a comparator, for example. Clock pulses 14 are illustrated under these waveforms and the PWM signal 16 is illustrated as a series of pulses. As is illustrated in FIGS. 1A-1B, the leading edge of each pulse, in the PWM signal 16 is triggered by the clock signal 14. The trailing edge of each pulse is triggered when the rising ramp signal 12 reaches the error signal Verror. Thus, as noted above, and as can be seen in FIG. 1A, when the transient in the error signal Verror occurs when the circuit is ON, that is, during one of the pulses of the PWM signal 16, the pulse width thereof is adjusted in light of the load step up that is represented by the transient in FIG. 1A. In contrast, when the transient in the error signal Verror occurs during the OFF time of the circuit, that is, in between the pulses of the PWM signal 16, as illustrated in FIG. 2B, no adjustment is made until the next clock pulse 14, which turns the control circuit ON, that is, triggers the rising edge of the next pulse in the PWM signal 16.

FIGS. 2A-2B illustrate waveforms of a PWM control circuit utilizing a Leading Edge architecture. The error signal is similar to that of FIG. 1, however, is superimposed with a decreasing ramp signal 22. The clock pulses 24 and pulses of the PWM signal 26 are similarly illustrated together. As illustrated, the control circuit turns ON, that is, the leading edge of each pulse in the PWM signal 26 is triggered when the decreasing ramp signal 22 matches the error signal. The circuit turns OFF at the clock pulse 24. That is, the trailing edge of each pulse of the PWM signal 26, is triggered by the clock pulses 24. Thus, while the circuit can respond to a transient that occurs while it is OFF, as illustrated in FIG. 2A, the circuit must wait until the next clock cycle to respond when the transient occurs while the circuit is ON, as illustrated in FIG. 2B.

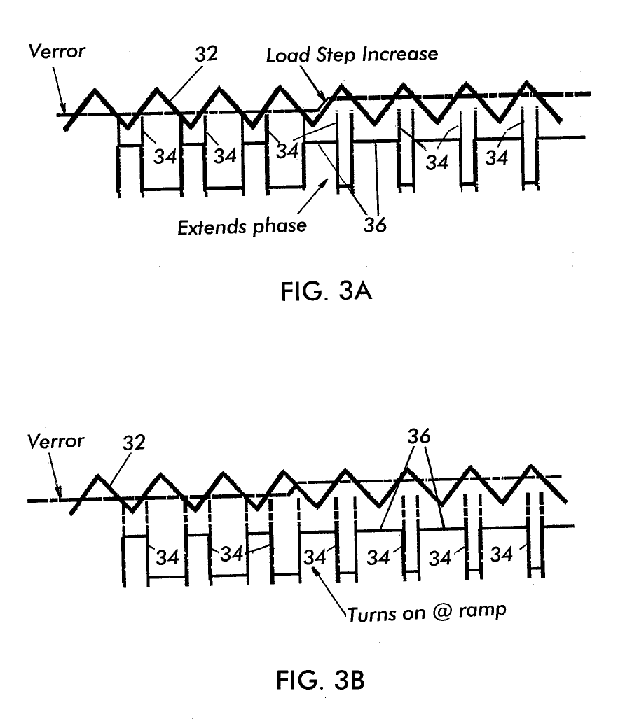

FIGS. 3A-3B illustrate waveforms of a PWM circuit utilizing a dual edge architecture. The error signal Verror is similar to that described above, however, is it superimposed on a symmetric increasing and decreasing ramp signal 32. That is, the ramp signal 32 of FIGS. 3A-3B increases for a half cycle and then decreases for a half cycle, as illustrated. The control circuit is turned ON and OFF, based purely on the comparison between the ramp signal 32 and the error signal Verror. That is, the leading and trailing edge of each of the pulses in the PWM signal 36 are triggered when the error signal matches the ramp signal. While this architecture avoids reliance on the clock pulses 34, and thus, clock delays, it is very sensitive to noise in the error signal. As a result, it would be easy for a pulse to be inadvertently triggered in the PWM signal 36.

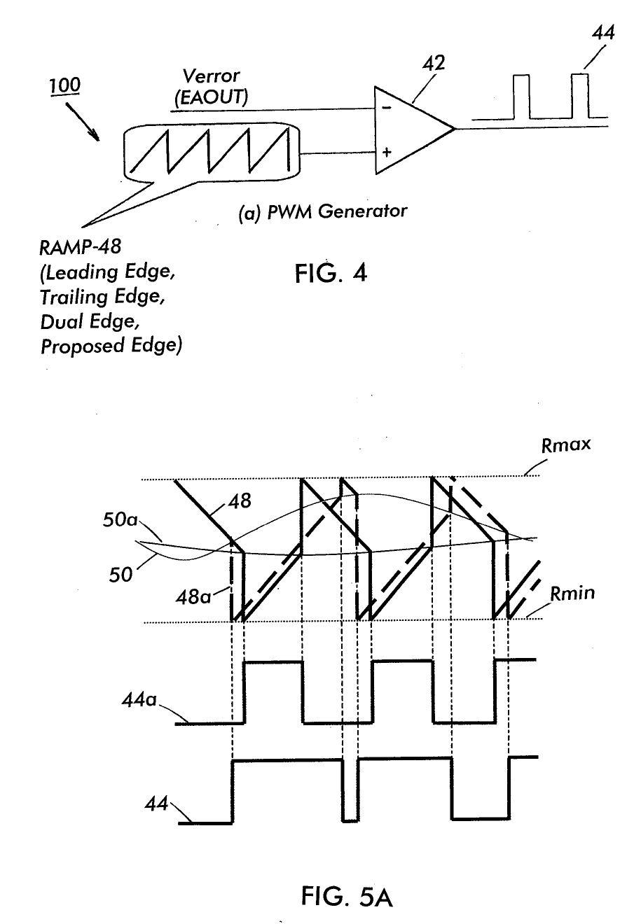

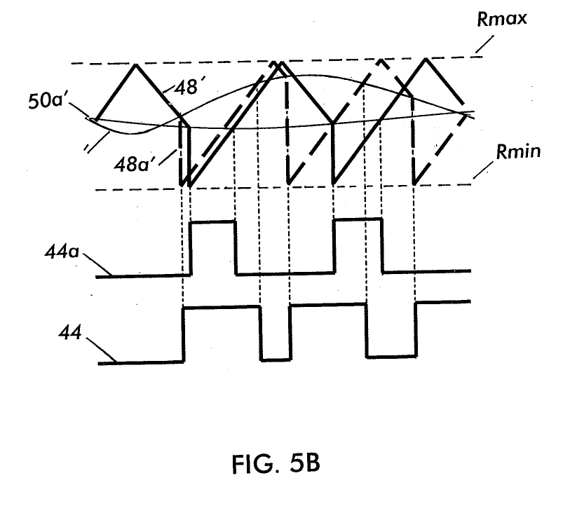

As illustrated in FIG. 4, a PWM control circuit 100 in accordance with an embodiment of the present invention may be similar to conventional PWM control circuits. A saw tooth, or ramp signal 48, generically illustrated in FIG. 4 and is provided as one input to the comparator 42. The other input of the comparator 103 is provided with an error signal Verror. As noted above, the error signal Verror is commonly obtained from the output of an error amplifier, and thus, is also designated at EAOUT in FIG. 4. The pulse width modulated signal 44 is provided based on a comparison of the saw tooth (ramp) waveform with the error signal Verror (EAOUT). The circuit 100 is implemented in much the same manner as a conventional PWM control circuit, however, it incorporates the advantages of all of Trailing Edge, Leading Edge and Dual Edge control. Thus, the control circuit 100 is not constrained by clock cycles and is resistant to the effect of noise on the error signal Verror. Specifically, in the circuit 100 of the present application, a Trailing Edge (decreasing) ramp signal is used to determine the ON time, that is, to trigger the leading edge of the pulses of the PWM signal 44, and a leading edge (increasing) ramp signal is provided to set the OFF time, that is, to trigger the trailing edge of the pulse, such that the circuit 100 utilizes a new ramp signal 48 (See FIGS. 5A-5B).

More specifically, in accordance with one embodiment of the present application, described with reference to FIG. 5A, the new ramp signal 48 includes a first decreasing portion, that decreases at a first slew rate and a second increasing portion that increases as a second slew rate. In FIG. 5A, two error signals 50 and 50a are illustrated. Error signal 50 includes a substantial transient and error signal 50a represents only a minor variation in the error signal. When the first decreasing portion of the ramp signal matches the error signal 50 (or 50a) the ramp signal 48 drops substantially immediately to a ramp minimum value Rmin, as illustrated by the broken line 48a in FIG. 5A. Further, the leading edge of a pulse in the PWM signal 44 (and 44a) is triggered. The second increasing portion of the ramp signal 48a then begins as the ramp signal increases from the valley of the ramp signal at the second slew rate. When the increasing ramp signal 48a matches the error signal, the PWM signal 44 terminates, that is, the trailing edge is triggered and circuit 100 is OFF. At the same time, the ramp signal 98a rises substantially immediately to a maximum ramp value Rmax and then starts decreasing again at the first slew rate again, such that the first decreasing portion of the ramp signal begins again. When it reaches the error signal 50 (or 50a) again, the leading edge of the next pulse in the PWM signal 44 is triggered and the ramp signal again drops to the minimum ramp value Rmin again.

As can be seen in FIG. 5A, where the error signal remains substantially unchanged, as illustrated by error signal 50a, the ramp signal 48 maintains a constant shape and provides a PWM signal 44a that has substantially uniform pulses in pulse width and frequency. Thus, any minor transients that may result from noise in the error signal due to the error output amplifier, for example, does not affect the control circuit 100, or the PWM signal 44 (or 44a) provided thereby.

Further, with reference to FIG. 5B, in an alternative embodiment, when the first decreasing portion of the ramp signal 48′ matches the error signal 50′ (or 50a′) the ramp signal drops substantially immediately to the ramp minimum value Rmin′ in a manner similar to that described above, as illustrated by the broken line 48a′ in FIG. 5B. At the same time, the leading edge of the pulse in the PWM signal 44′ (or 44a′) is triggered. Thereafter, the ramp signal 48a′ increases at the second slew rate from the valley of the ramp signal. When the second increasing portion of the ramp signal 48a′ matches the error signal 50 (or 52), the PWM signal 44′ (or 44a′) terminates, that is, the trailing edge is triggered and the circuit 100 turns OFF. Thereafter, the ramp signal continues to rise to the ramp maximum value Rmax′ at the second slew rate. After reaching Rmax′, the ramp signal 48a′ begins decreasing again at the first slew rate, and the first decreasing portion of the ramp signal starts again. Further, similar to the embodiment of FIG. 5A, utilizing the error signal 50a′ which does not change substantially, the ramp signal 48′ maintains substantially the same shape and the resulting PWM signal 44a′ has a substantially constant pulse width and pulse frequency.

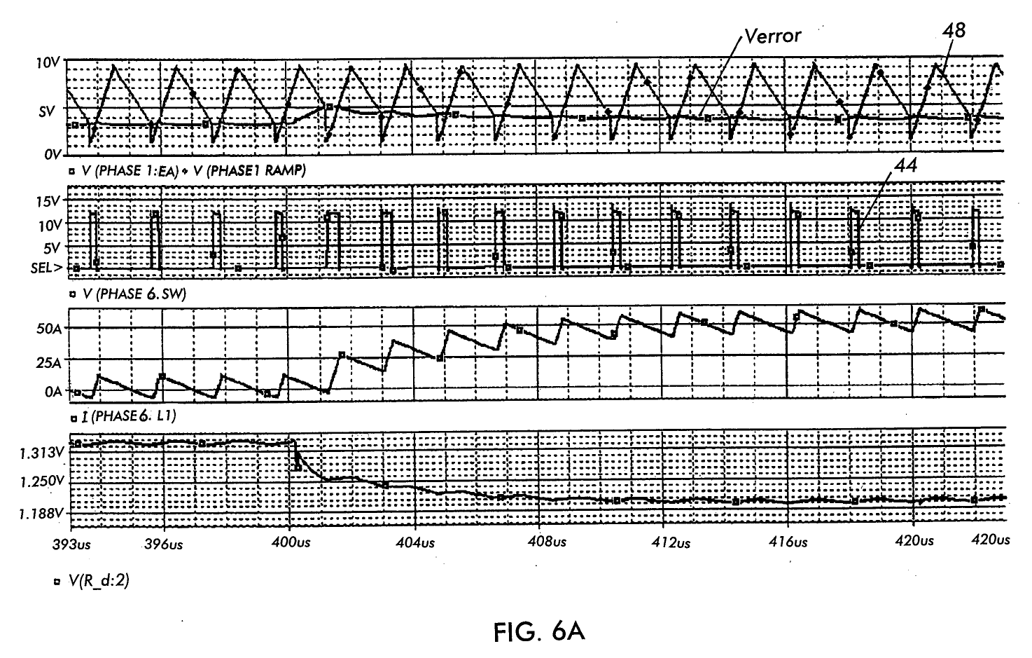

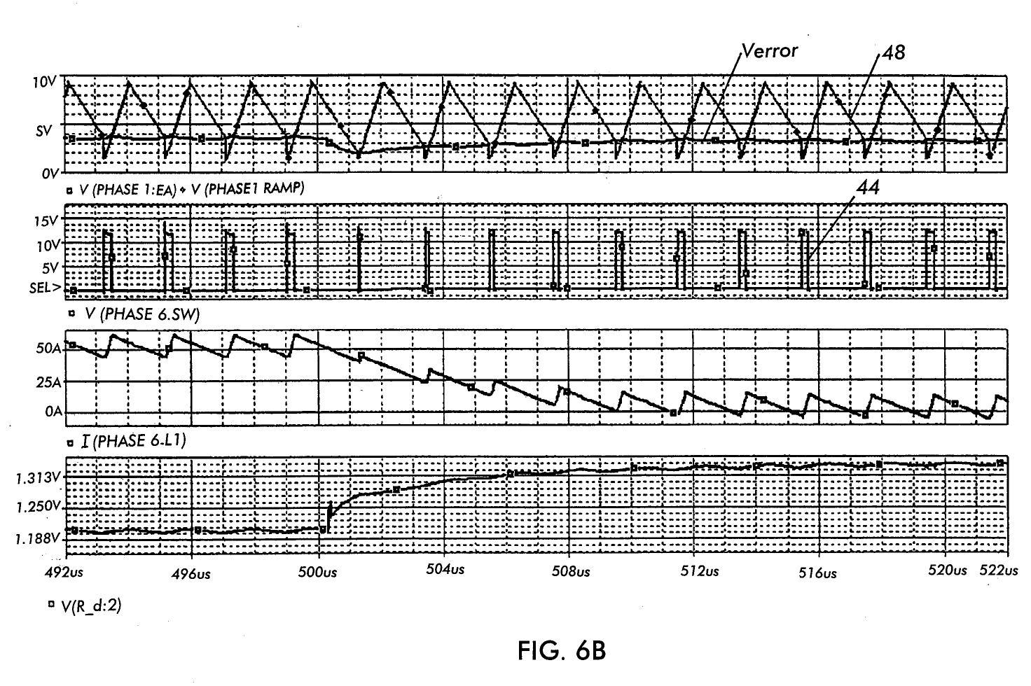

FIG. 6A illustrates a plurality of graphs illustrating data collected by simulating the circuit of FIG. 4 utilizing an error signal that represents a load step up. FIG. 6B illustrates a plurality of graphs illustrating data collected by simulating the circuit of FIG. 4 utilizing an error signal that represent a load step down. As is illustrated in FIGS. 6A and 6B, the simulated circuit of FIG. 4 provides excellent results and responsive PWM signals.

Thus, the PWM control circuit 100 of the present application provides for PWM control that is clock independent and at the same time, resistant to noise in the error signal. The control circuit 100 utilizes a comparator 42 to provide a desired PWM signal 44, 44a, however, a modified ramp signal 48, 48a is provided to this comparator. The modified ramp signal 48, 48a provides PWM adjustments immediately based on the comparison of the ramp signal to the error signal, while remaining very resistant to noise in the error signal.

Further, while the control circuit 100 of the present application has been described with reference to pulse width modulation, however, it is equally suitable for use with pulse frequency modulation control as well. For example, as is illustrated in FIG. 6A, the frequency of the PWM signal 44 is increased during load step-up and is decreased during load step down, as illustrated in FIG. 6B.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

What is claimed is:

1. A pulse width modulation control circuit operable to provide a pulse width modulation signal comprises:
a comparator operable to compare a first input to a second input and to provide the pulse width modulation signal based on the comparison, wherein
the first input is an error signal;
the second input is a ramp signal, wherein a first portion of the ramp is a decreasing ramp signal having a first slew rate and a second portion of the ramp signal is an increasing ramp signal having a second slew rate.

2. The pulse width modulation control circuit of claim 1, wherein a leading edge of a pulse of the pulse width modulation signal is triggered when the first decreasing portion of the ramp signal decreases to match the error signal, and wherein
the ramp signal drops to a predetermined ramp minimum value substantially immediately after the first decreasing portion of the ramp signal decreases to match the error voltage, and then increase at the second slew rate to implement the second increasing portion of the ramp signal.

3. The pulse width modulation control circuit of claim 2, wherein a trailing edge of the pulse of the pulse width modulation signal is triggered when the second increasing portion of the ramp signal increases to match the error signal, and wherein
the ramp signal rises to a predetermined maximum ramp value substantially immediately after the second increasing portion of the ramp signal increases to match the error signal, and thereafter decreases at the first slew rate.

4. The pulse width modulation control circuit of claim 3, wherein a trailing edge of the pulse of the pulse width modulation signal is triggered when the second increasing portion of the ramp signal increases to match the error signal, and wherein
the ramp signal continues to rise at the second slew rate to a predetermined maximum ramp value after the second portion of the ramp signal increases to match the error signal and thereafter decreases at the first slew rate.

5. A method of providing a pulse width modulation signal to provide pulse width modulation comprising:
comparing an error signal to a ramp signal and generating the pulse width modulation signal based on the comparing step, wherein,
the ramp signal includes a first decreasing portion having a first slew rate and a second increasing portion having a second slew rate, and wherein
a leading edge of a pulse of the pulse width modulation signal is triggered when the first decreasing portion of the ramp signal decreases to match the error signal and a trailing edge of the pulse of the pulse width modulation signal is triggered when the increasing portion of the ramp signal increases to match the error signal.

6. The method of claim 5, further comprising:
reducing the ramp signal to a ramp minimum value substantially immediately after the first decreasing portion of the ramp signal decreases to match the error signal; and
raising the ramp signal at the second slew rate to provide the second increasing portion of the ramp signal after the first decreasing portion of the ramp signal decreases to match the error signal.

7. The method of claim 6, further comprising:
increasing the ramp signal to a ramp maximum value substantially immediately after the second increasing portion of the ramp signal matches the error signal; and
decreasing the ramp signal from the maximum ramp value at the first slew rate thereafter.

8. The method of claim 6, further comprising:
increasing the ramp signal to a ramp maximum value at the second slew rate after the second increasing portion of the ramp signal matches the error signal; and
decreasing the ramp signal from the maximum ramp value at the first slew rate thereafter.
